(19) United States
(12) Patent Application Publication
(10) Pub. No.: US 2013/0314611 A1
(43) Pub. Date: Nov. 28, 2013

(54) TELEVISION AND ELECTRONIC APPARATUS

(71) Applicants: Isao Okutsu, Akishima-shi (JP); Chiari Shimizu, Fussa-shi (JP)

(72) Inventors: Isao Okutsu, Akishima-shi (JP); Chiari Shimizu, Fussa-shi (JP)

(21) Appl. No.: 13/708,212

(22) Filed: Dec. 7, 2012

(30) Foreign Application Priority Data
May 22, 2012 (JP) 2012-116554

(51) Int. Cl. H04N 5/64; H05K 5/02

(52) U.S. Cl. CPC H04N 5/64; H05K 5/0234
USPC 348/739; 361/679.01

(57) ABSTRACT

According to one embodiment, an electronic apparatus includes a housing, a display configured to be movable relative to the housing, and a supporter attached to the display and configured to be movable in the housing.

### CROSS-REFERENCE TO RELATED APPLICATIONS

This application is based upon and claims the benefit of priority from Japanese Patent Application No. 2012-116554, filed May 22, 2012, the entire contents of which are incorporated herein by reference.

### FIELD

Embodiments described herein relate generally to electronic apparatuses including televisions.

### BACKGROUND

Electronic apparatuses that can be bent have been proposed.

### BRIEF DESCRIPTION OF THE DRAWINGS

A general architecture that implements the various features of the embodiments will now be described with reference to the drawings. The drawings and the associated descriptions are provided to illustrate the embodiments and not to limit the scope of the invention.

FIG. 1 is an exemplary front view of a television according to a first embodiment;

FIG. 2 is an exemplary perspective view of the television illustrated in FIG. 1;

FIG. 3 is an exemplary perspective view of an electronic apparatus according to a second embodiment;

FIG. 4 is an exemplary perspective view of the electronic apparatus illustrated in FIG. 3;

FIG. 5 is an exemplary perspective view of the electronic apparatus illustrated in FIG. 3;

FIG. 6 is an exemplary cross-sectional view of the electronic apparatus illustrated in FIG. 3;

FIG. 7 is an exemplary perspective view illustrating a display illustrated in FIG. 6;

FIG. 8 is an exemplary perspective view of a supporter illustrated in FIG. 7;

FIG. 9 is an exemplary cross-sectional view of the electronic apparatus illustrated in FIG. 3;

FIG. 10 is an exemplary cross-sectional view of the electronic apparatus illustrated in FIG. 3;

FIG. 11 is an exemplary cross-sectional view of the electronic apparatus illustrated in FIG. 3;

FIG. 12 is an exemplary cross-sectional view of an electronic apparatus according to a third embodiment;

FIG. 13 is an exemplary cross-sectional view of the electronic apparatus illustrated in FIG. 12;

FIG. 14 is an exemplary perspective view illustrating a part of an electronic apparatus according to a fourth embodiment in an enlarged scale;

FIG. 15 is an exemplary cross-sectional view of the electronic apparatus illustrated in FIG. 14;

FIG. 16 is an exemplary cross-sectional view of an electronic apparatus according to a fifth embodiment;

FIG. 17 is an exemplary cross-sectional view of an electronic apparatus according to a sixth embodiment;

FIG. 18 is an exemplary cross-sectional view of an electronic apparatus according to a seventh embodiment;

FIG. 19 is an exemplary cross-sectional view of an electronic apparatus according to an eighth embodiment;

FIG. 20 is an exemplary cross-sectional view of an electronic apparatus according to a ninth embodiment; and

FIG. 21 is an exemplary perspective view illustrating a display according to a tenth embodiment.

### DETAILED DESCRIPTION

Various embodiments will be described hereinafter with reference to the accompanying drawings.

In general, according to one embodiment, an electronic apparatus comprises a housing, a display configured to be movable relative to the housing, and a supporter attached to the display and configured to be movable in the housing.

Hereinafter, exemplary embodiments will be described with reference to the accompanying drawings. In this specification, some components are expressed by two or more terms. Those terms are just examples. Those components may be further expressed by another or other terms. And the other components which are not expressed by two or more terms may be expressed by another or other terms.

### First Embodiment

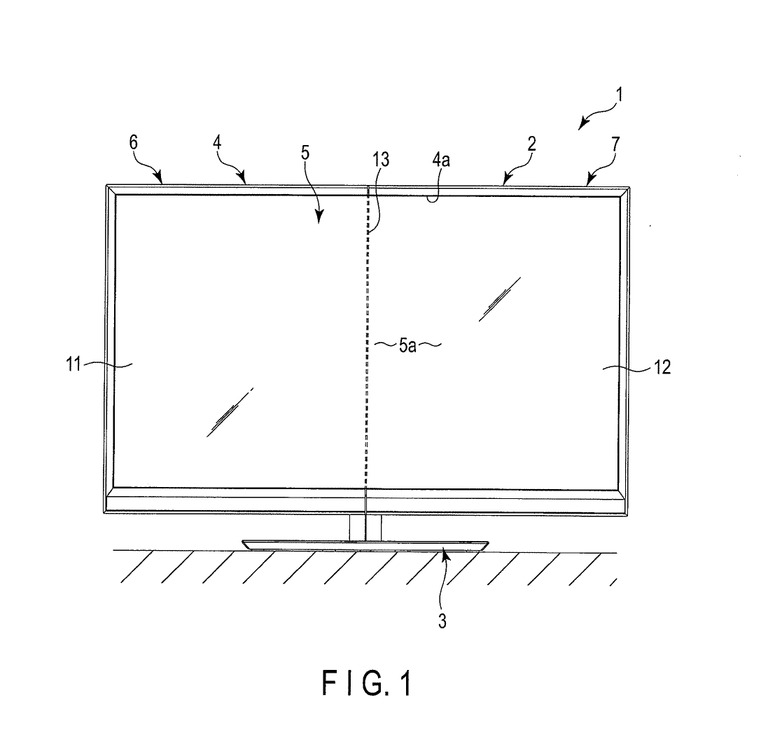

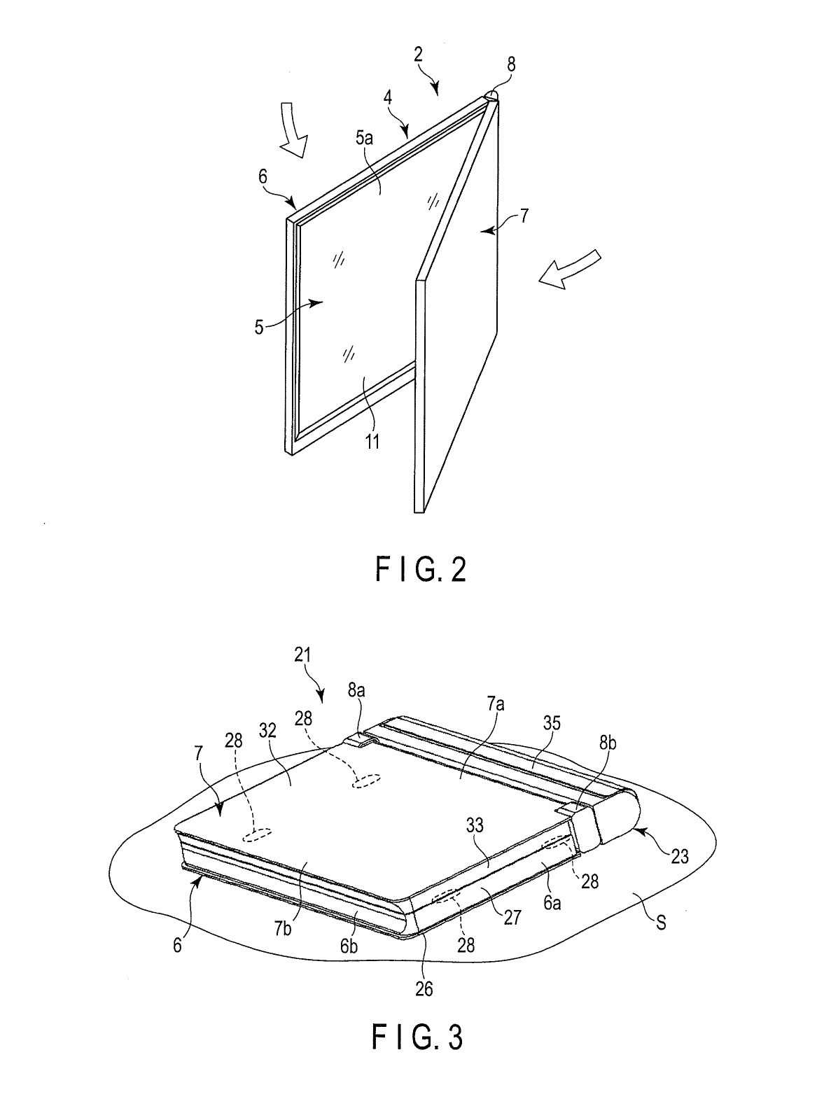

FIGS. 1 and 2 illustrate a television 1 according to a first embodiment. The television 1 is an example of an “electronic apparatus.” The television 1 includes a display unit 2 and a stand 3 (i.e., a supporter, e.g., a rack) that supports the display unit 2. The television 1 may be a wall-mounted type television that does not include the stand 3.

As illustrated in FIG. 1, the display unit 2 includes a flat box-like housing 4 and a display 5 that is accommodated in the housing 4. The display 5 is a flexible display (e.g., sheet display) having bendability (i.e., flexibility). The display 5 includes a display screen 5a on which images and videos are displayed. The housing 4 includes an opening 4a through which the display screen 5a is exposed.

As illustrated in FIGS. 1 and 2, the housing 4 includes a first exterior member 6 (i.e., a first housing, a first member, or a first portion) and a second exterior member 7 (i.e., a second housing, a second member, or a second portion). The first exterior member 6 and the second exterior member 7 are rotatably connected to each other by a hinge 8.

The television 1 according to the present embodiment is configured to be bent (i.e., folded) about the hinge 8. The television 1 can be deformed into a first state where the first exterior member 6 and the second exterior member 7 overlap each other and a second state where the first exterior member 6 and the second exterior member 7 are away from each other so that the display screen 5a is exposed to the outside.

The display 5 includes a first display portion 11 (i.e., a first portion or a first region) that is positioned in the first exterior member 6, a second display portion 12 (i.e., a second portion or a second region) that is positioned in the second exterior member 7, and a third display portion 13 (i.e., a third portion or a third region) that is positioned between the first display portion 11 and the second display portion 12. The display 5 extends from the first exterior member 6 to the second exterior member 7. The display 5 includes a large display screen 5a that extends over the first exterior member 6 and the second exterior member 7.

The second display portion 12 is fixed to the second exterior member 7. On the other hand, the first display portion 11 is not fixed to the first exterior member 6. The first display portion 11 is movable relative to the first exterior member 6. The first display portion 11 is configured to be slid within the first exterior member 6 when the second exterior member 7 is rotated (opened or closed) relative to the first exterior member 6. The third display portion 13 is bent when the first exterior member 6 and the second exterior member 7 overlap each other.

A detailed structure of the television 1 is substantially the same as that of an electronic apparatus 21 according to a second embodiment. Therefore, the electronic apparatus 21 according to the second embodiment will be described in detail, and detailed description of the television 1 will not be provided. Configurations having the same or similar functions in the first and second embodiments will be denoted by the same reference numerals.

### Second Embodiment

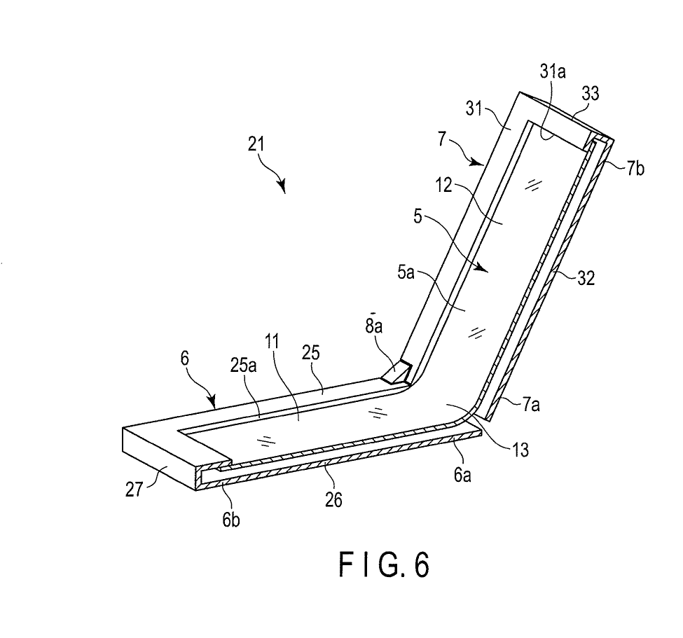

Next, the electronic apparatus 21 according to the second embodiment will be described with reference to FIGS. 3 to 11. As illustrated in FIGS. 3 to 5, the electronic apparatus 21 according to the present embodiment is a notebook-type portable computer (i.e., note PC), for example. Further, the electronic apparatus 21 according to the present embodiment is a tablet-type portable computer (i.e., tablet PC) that does not have a keyboard, for example. Electronic apparatuses to which the embodiments described herein can be applied are not limited to the above examples. The embodiments described herein can be broadly applied to various electronic apparatuses such as, for example, a television, a mobile phone (including a smart phone), or a game machine.

As illustrated in FIGS. 3 to 5, the electronic apparatus 21 includes a first housing 6, a second housing 7, a third housing 23, and hinges 8a and 8b. The first housing 6, the second housing 7, and the third housing 23 form an outer body of the electronic apparatus 21 and are exposed to the outside. The first housing 6, the second housing 7, and the third housing 23 form a part of the external surface (i.e., an outer surface or a surface perceived by a user) of the electronic apparatus 21. The first housing 6, the second housing 7, and the third housing 23 are exterior members in which components are accommodated.

The first housing 6 (i.e., a first exterior member, a first member, or a first portion) corresponds to the first exterior member 6 of the first embodiment. The first housing 6 includes a first wall 25 (e.g., an upper wall or a front wall), a second wall 26 (e.g., a lower wall, a bottom wall, or a back wall), and a third wall 27 (e.g., a circumferential wall or a side wall) and has a flat box-like shape.

The first wall 25 includes a first opening 25a through which a part of the display 5 is exposed. The second wall 26 is positioned on a side opposite to the first wall 25. The second wall 26 extends substantially in parallel with the first wall 25, for example. The second wall 26 faces an upper surface S (i.e., a mounting surface, an outer surface, or an outer mounting surface) of a table when the electronic apparatus 21, for example is placed on the table.

A plurality of legs 28 (i.e., supporters), for example, is provided on the second wall 26. The legs 28 make contact with the upper surface S of the table and support the electronic apparatus 21 when the electronic apparatus 21 is placed on the table in a folded state. The third wall 27 extends in a direction crossing (e.g., substantially orthogonal to) the first wall 25 and the second wall 26 and connects a peripheral portion of the first wall 25 and a peripheral portion of the second wall 26.

The first housing 6 includes a first end portion 6a (e.g., a rear end portion) and a second end portion 6b (e.g., a front end portion). The hinges 8a and 8b are connected to the first end portion 6a. The second end portion 6b is positioned on a side opposite to the first end portion 6a. Herein, the directions up, down, left, and right are defined as seen from the user. Moreover, the side closer to the user is defined as “front,” and the side further from the user is defined as “rear.”

As illustrated in FIGS. 3 to 5, the second housing 7 (i.e., a second exterior member, a second member, or a second portion) corresponds to the second exterior member 7 of the first embodiment. The second housing 7 includes a first wall 31 (e.g., an upper wall or a front wall), a second wall 32 (e.g., a lower wall, a bottom wall, or a back wall), and a third wall 33 (e.g., a circumferential wall or a side wall) and has a flat box-like shape. Herein, the directions up and down, of the second housing 7 are defined based on a state where the first wall 31 faces upward.

The first wall 31 includes a second opening 31a through which a part of the display 5 is exposed. The second wall 32 is positioned on a side opposite to the first wall 31. The second wall 32 extends substantially in parallel with the first wall 31, for example. The third wall 33 extends in a direction crossing (e.g., substantially orthogonal to) the first wall 31 and the second wall 32 and connects a peripheral portion of the first wall 31 and a peripheral portion of the second wall 32.

The second housing 7 includes a first end portion 7a (e.g., a lower end portion) and a second end portion 7b (e.g., an upper end portion). The hinges 8a and 8b are connected to the first end portion 7a. The second end portion 7b is positioned on a side opposite to the first end portion 7a.

The hinges 8a and 8b rotatably (i.e., openably) connect the first end portion 6a of the first housing 6 and the first end portion 7a of the second housing 7. In this way, the electronic apparatus 21 can be bent (i.e., folded). The electronic apparatus 21 can be deformed into a first state where the first housing 6 and the second housing 7 overlap each other and a second state where the first housing 6 and the second housing 7 are away from each other so that the display screen 5a is exposed to the outside.

As illustrated in FIGS. 3 to 5, the third housing 23 is positioned on a rear side of the first housing 6. The third housing 23 is provided at a position such that the third housing 23 does not overlap the first housing 6 and the second housing 7 when the first housing 6 and the second housing 7 overlap each other. A battery 35, for example, is attached to the third housing 23.

The third housing 23 is thicker than the first housing 6 and thicker than the second housing 7. The thickness of the third housing 23 is substantially the same as the sum of the thicknesses of the first housing 6 and the second housing 7. In a state where the first housing 6 and the second housing 7 overlap each other, a surface (e.g., an upper surface) of the third housing 23 is positioned substantially on the same plane as a surface (e.g., an upper surface) of the second housing 7.

As illustrated in FIGS. 3 to 5, the third housing 23 faces the first end portion 6a of the first housing 6 and the first end portion 7a of the second housing 7. The third housing 23 has substantially the same width as the first housing 6 and the second housing 7. The third housing 23 is connected to the first end portion 6a of the first housing 6 and the first end portion 7a of the second housing 7 by the hinges 8a and 8b. The third housing 23 is configured to be inclined downward with the pivoting of the second housing 7 when the first housing 6 and the second housing 7 are separated from each other. In this way, the first end portion 6a of the first housing 6 can be raised by the third housing 23, and the electronic apparatus 21 is at an inclined posture.

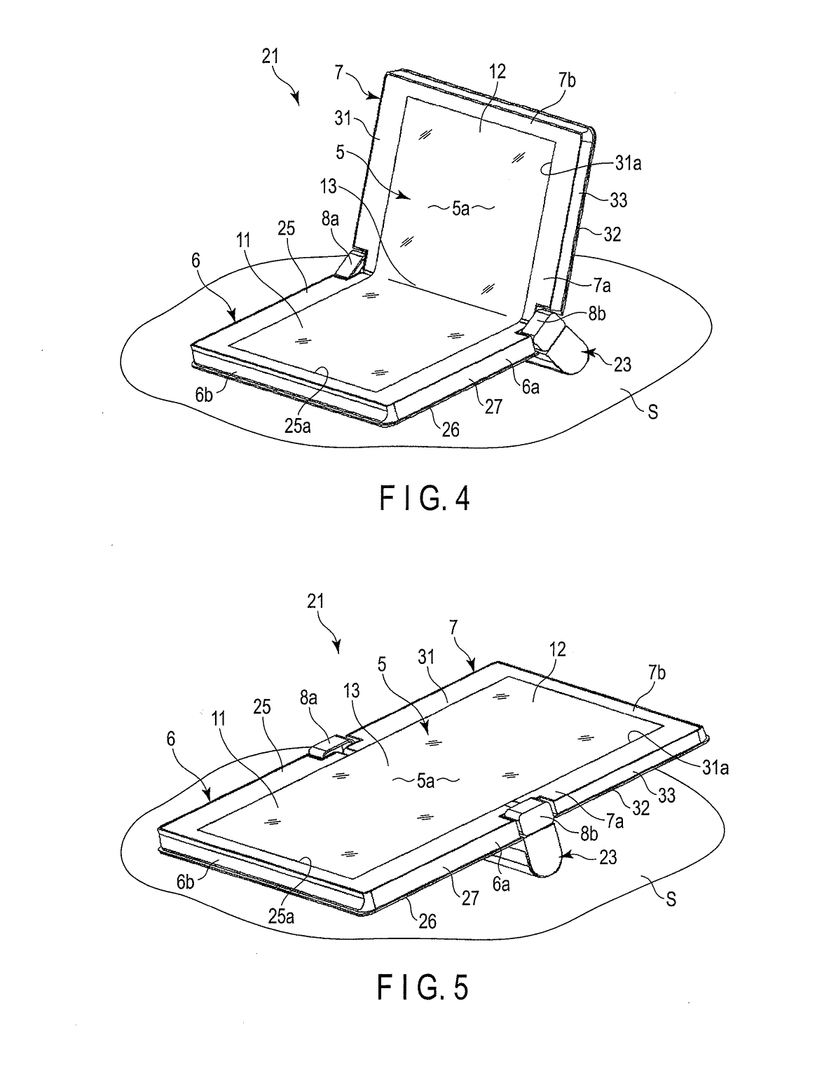

As illustrated in FIGS. 4 to 6, the electronic apparatus 21 includes a display 5. The display 5 is a flexible display (e.g., sheet display) having bendability (i.e., flexibility), for example. The display 5 is an organic EL display, for example, but is not limited to this. The display 5 includes a display screen 5a on which images and videos are displayed.

As illustrated in FIGS. 4 to 6, the display 5 includes a first display portion 11 (i.e., a first portion or a first region), a second display portion 12 (i.e., a second portion or a second region), and a third display portion 13 (i.e., a third portion or a third region). The first display portion 11 is positioned in the first housing 6. The second display portion 12 is positioned in the second housing 7. The third display portion 13 is positioned between the first display portion 11 and the second display portion 12. The display 5 extends from the first housing 6 to the second housing 7. The display 5 includes the large display screen 5a that extends over the first housing 6 and the second housing 7.

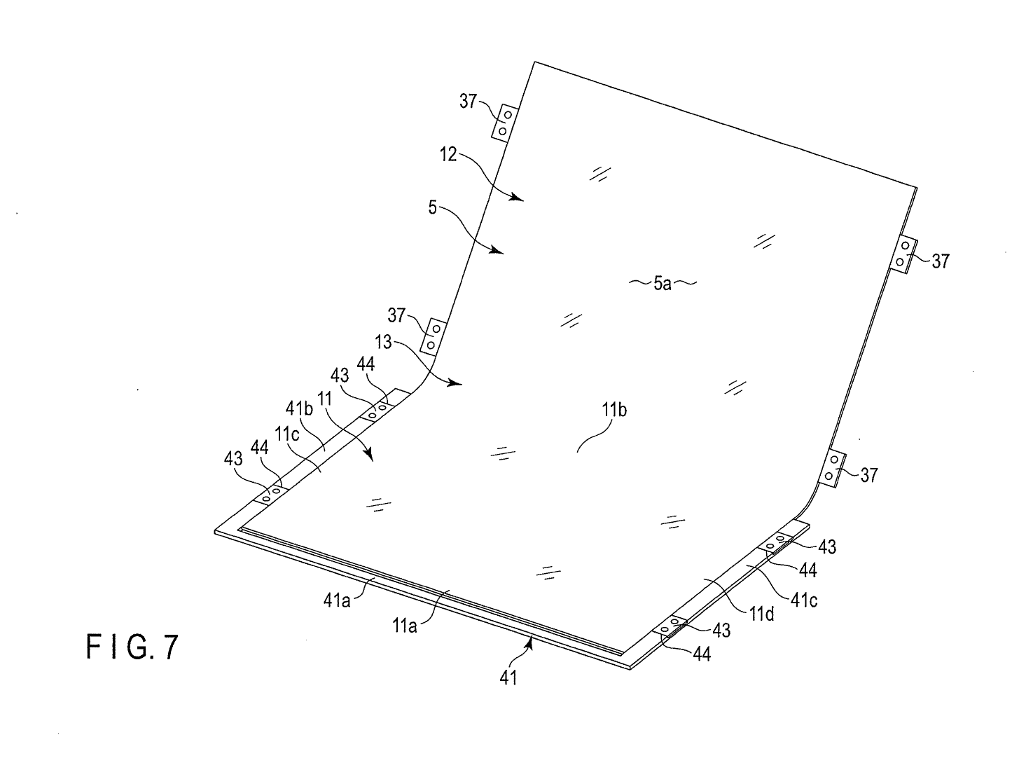

The second display portion 12 is fixed to the second housing 7. Specifically, as illustrated in FIG. 7, the second display portion 12 includes a plurality of (e.g., four) first fixing portions 37 (i.e., attachment portions). The first fixing portion 37 is provided, for example, by extending a part of the display 5 to the outside. The first fixing portion 37 may be provided by attaching other members (e.g., components) to the display 5. Moreover, the second display portion 12 may be fixed to the hinges 8a and 8b or the other members instead of the second housing 7.

The first fixing portion 37 is fixed to the second housing 7 by a fixing member such as a screw or by welding, for example. In this way, the display 5 is fixed to the second housing 7. The first fixing portion 37 may not be attached directly to the second housing 7. The first fixing portion 37 may be attached to another separate piece and be attached to the second housing 7 via the separate piece, for example.

On the other hand, the first display portion 11 is not fixed to the first housing 6. The first display portion 11 is movable relative to the first housing 6. The first display portion 11 is guided to the first housing 6 and slid inside the first housing 6 when the second housing 7 is rotated (e.g., opened or closed) relative to the first housing 6. The first display portion 11 is slid in the front-rear direction of the first housing 6. That is, the first display portion 11 is slid in an arrangement direction of the first display portion 11 and the second display portion 12.

As illustrated in FIG. 7, a supporter 41 (i.e., a holder, a guide, a frame, or a casing) is attached to the first display portion 11. Here, the first display portion 11 includes a first end portion 11a, a second end portion 11b, a third end portion 11c, and a fourth end portion 11d. The first end portion 11a is a front end portion, for example. The first end portion 11a is positioned on a side opposite to the second display portion 12. The second end portion 11b is a rear end portion, for example. The second end portion 11b is positioned on a side opposite to the first end portion 11a and is adjacent to the third display portion 13. The first end portion 11a and the second end portion 11b extend in a direction crossing (e.g., substantially orthogonal to) the sliding direction of the first display portion 11.

The third end portion 11c is a left end portion, for example. The fourth end portion 11d is a right end portion, for example, and is positioned on a side opposite to the third end portion 11c. The third end portion 11c and the fourth end portion 11d extend in a direction crossing (e.g., substantially orthogonal to) the first end portion 11a and the second end portion 11b. The third end portion 11c and the fourth end portion 11d extend in the sliding direction of the first display portion 11.

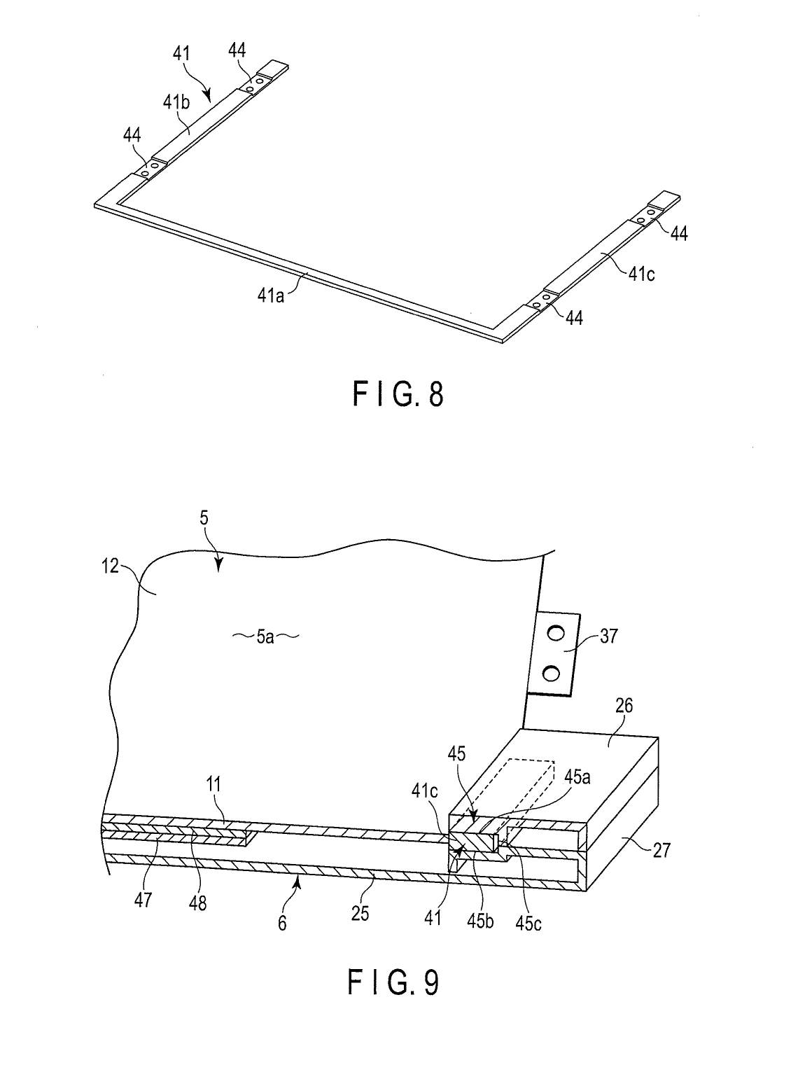

As illustrated in FIGS. 7 and 8, the supporter 41 according to the present embodiment has a U-shape in which one side is open. The supporter 41 includes a first portion 41a, a second portion 41b, and a third portion 41c. The first portion 41a extends over the entire length of the first end portion 11a along the first end portion 11a of the first display portion 11. The second portion 41b extends over substantially the entire length of the third end portion 11c along the third end portion 11c of the first display portion 11. The second portion 41b is connected to the first portion 41a. The third portion 41c extends substantially the entire length of the fourth end portion 11d along the fourth end portion 11d of the first display portion 11. The third portion 41c is connected to the first portion 41a. The supporter 41 surrounds the first display portion 11 from three directions. The supporter 41 is formed of metal, for example, and is harder (i.e., has higher rigidity) than the display 5.

As illustrated in FIG. 7, a second fixing portion 43 is provided on the first display portion 11. The second fixing portion 43 is provided, for example, by extending a part of the display 5 to the outside. The second fixing portion 43 may be provided by attaching other members (e.g., components) to the display 5.

The third end portion 11c of the first display portion 11 includes two second fixing portions 43, for example. The two second fixing portions 43 are separated in the sliding direction of the first display portion 11. Similarly, the fourth end portion 11d of the first display portion 11 includes two second fixing portions 43, for example. The two second fixing portions 43 are separated in the sliding direction of the first display portion 11.

As illustrated in FIGS. 7 and 8, the supporter 41 includes a recess 44 (i.e., an attachment portion) at a position corresponding to the second fixing portion 43, to which the second fixing portion 43 is attached. The recess 44 is formed in the second portion 41b and the third portion 41c of the supporter 41. The second fixing portion 43 is attached to the recess 44 of the supporter 41, and is attached to the supporter 41 by a fixing member such as a screw or by welding, for example. In this way, the first display portion 11 and the supporter 41 are integrated.

As illustrated in FIG. 7, the second portion 41b of the supporter 41 is provided over substantially the entire length of the third end portion 11c of the first display portion 11 so as not to be bent in the sliding direction of the first display portion 11. Similarly, the third portion 41c of the supporter 41 is provided over substantially the entire length of the fourth end portion lid of the first display portion 11 so as not to be bent in the sliding direction of the first display portion 11. In this way, the first display portion 11 is suppressed from being bent in the sliding direction thereof. That is, the first display portion 11 is suppressed from being bent between the first end portion 11a and the second end portion 11b of the first display portion 11. On the other hand, the bending between the third end portion 11c and the fourth end portion 11d of the first display portion 11 is suppressed by the first portion 41a of the supporter 41.

As illustrated in FIG. 9, the first housing 6 includes a guiding portion 45 (i.e., a guide) to which the supporter 41 is guided. The guiding portion 45 according to the present embodiment is a rail (i.e., a guide rail, a slide rail, or a groove) provided in the first housing 6, for example. The guiding portion 45 is formed on both sides of the first display portion 11 so as to receive the second portion 41b and the third portion 41c of the supporter 41, for example.

The guiding portion 45 extends in the sliding direction of the first display portion 11. The guiding portion 45 according to the present embodiment includes a first surface 45a, a second surface 45b, and a third surface 45c. The first surface 45a extends substantially in parallel with the first display portion 11. The first surface 45a faces the supporter 41 from the upper side, for example.

The second surface 45b is positioned on a side opposite to the first surface 45a and extends substantially in parallel with the first surface 45a. The second surface 45b faces the supporter 41 from a side opposite to the first surface 45a, for example, from the lower side. The third surface 45c extends between the first surface 45a and the second surface 45b. The third surface 45c extends in the thickness direction of the first housing 6, for example. The third surface 45c faces the supporter 41 from a direction different from that of the first surface 45a and the second surface 45b, for example, from a lateral side.

As illustrated in FIG. 9, the first housing 6 includes a supporting portion 47 that is positioned under the first display portion 11 so as to support the first display portion 11, for example. A member 48 (a material or a component) is provided between the supporting portion 47 and the first display portion 11. The member 48 is a member that decreases the friction between the supporting portion 47 and the first display portion 11. The member 48 is a member having a smaller frictional coefficient than the first housing 6, for example, and is a silicon sheet, for example.

Further, instead of providing the member 48, a friction reducing portion such as a slit or a notch may be formed in the supporting portion 47. By providing a slit or the like, it is possible to decrease the contacting area between the supporting portion 47 and the first display portion 11 and to decrease friction.

Next, the operation of the electronic apparatus 21 according to the present embodiment will be described.

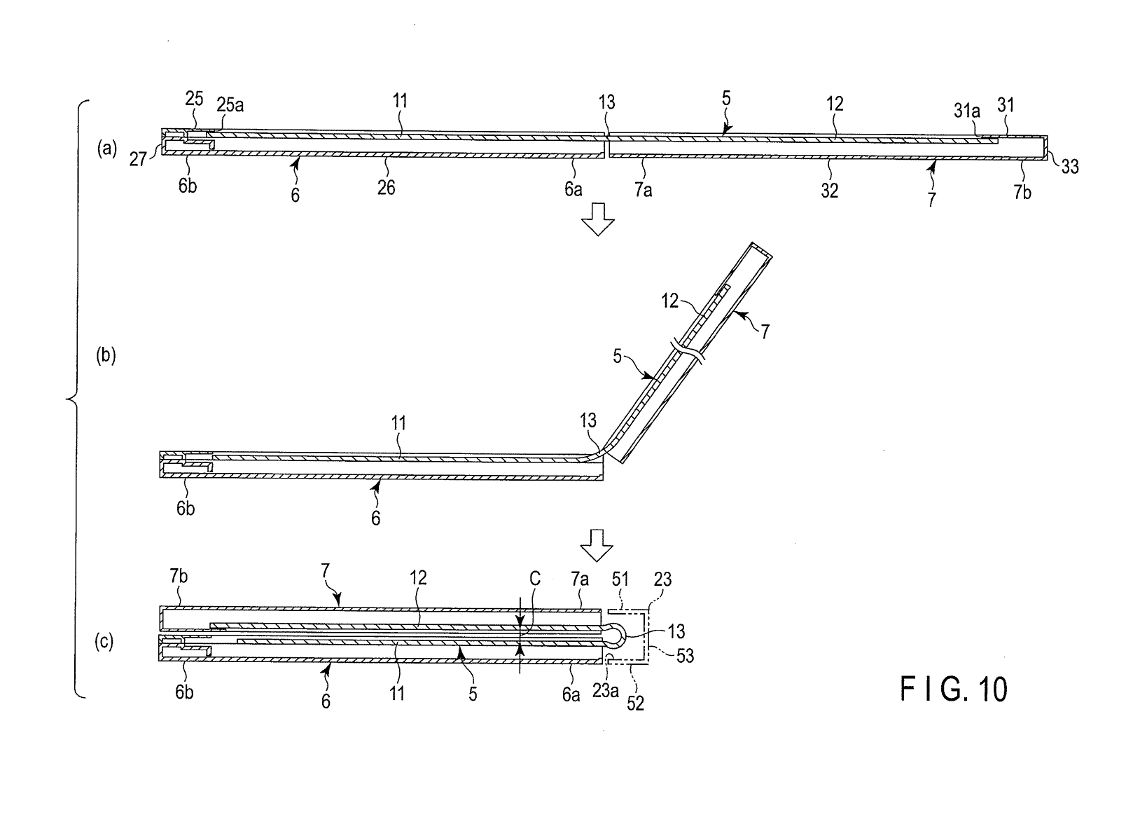

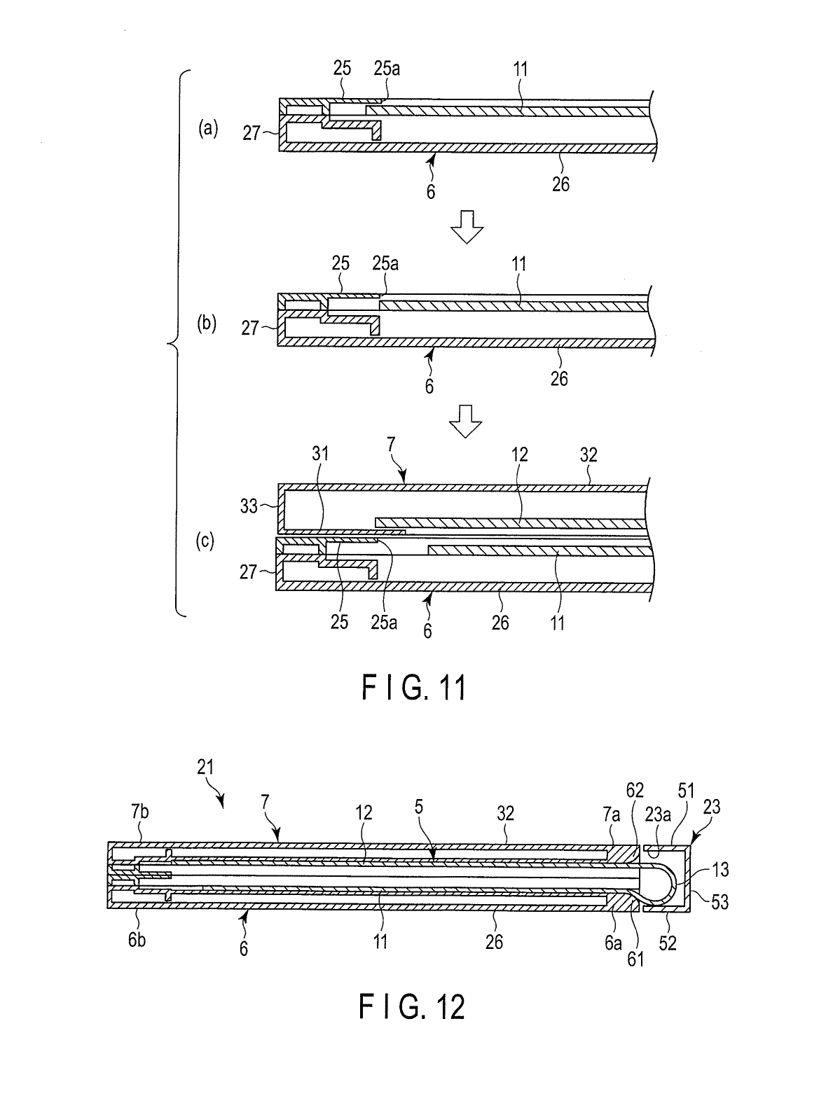

As illustrated in FIGS. 10 and 11, the supporter 41 is configured to be guided to the guiding portion 45 and to be slid in the front-back direction within the first housing 6 when the first housing 6 and the second housing 7 are rotated (e.g., opened or closed). Specifically, as illustrated in (a) of FIG. 10, the display 5 is extended longest in a state where the electronic apparatus 21 is open. In this state, the first display portion 11 is closest to the second end portion 6b (e.g., the front end portion) of the first housing 6.

As illustrated in (b) of FIG. 10, in a state where the second housing 7 is erected, the first display portion 11 is slid toward the hinges 8a and 8b and is moved away from the second end portion 6b of the first housing 6. Further, as illustrated in (c) of FIG. 10, in a state where the electronic apparatus 21 is folded, the first display portion 11 is slid further toward the hinges 8a and 8b and is separated furthest from the second end portion 6b of the first housing 6.

As illustrated in FIG. 10, the third display portion 13 is bent when the first housing 6 and the second housing 7 overlap each other (i.e., the electronic apparatus 21 is folded). The third display portion 13 projects outward from a position between the first housing 6 and the second housing 7. A part of the third display portion 13 project further rearward than the hinges 8a and 8b when the first housing 6 and the second housing 7 overlap each other. The third display portion 13 is bent to form a circular arc that has a diameter greater than a gap C between the first display portion 11 and the second display portion 12. In the present embodiment, the third display portion 13 is bent to form a circular arc that has a diameter greater than the gap between the first housing 6 and the second housing 7 when the first housing 6 and the second housing 7 overlap each other.

Here, a minimum radius of bending of a display is determined based on a material thereof. The “minimum radius of bending” is a radius at which a problem may occur in the display when the display is bent to form a circular arc having a radius smaller than the minimum radius of bending.

In the present embodiment, the first display portion 11 is slid to a large extent such that the radius of a circular arc portion of the third display portion 13 is greater than the minimum radius of bending of the display 5 when the electronic apparatus 21 is folded.

As illustrated in FIG. 10, the third housing 23 includes an opening 23a that faces the first housing 6 and the second housing 7, for example. At least a part of the third display portion 13 enters into the third housing 23 through the opening 23a. The third housing 23 includes a first wall 51 (e.g., an upper wall), a second wall 52 (e.g., a lower wall or a bottom wall), and a third wall 53 (e.g., a back wall or a rear wall).

In a state where the first housing 6 and the second housing 7 overlap each other, the first wall 51 is positioned substantially on the same plane as the upper surface of the second housing 7. The second wall 52 is positioned substantially on the same plane as the lower surface of the first housing 6. The third wall 53 extends between the first wall 51 and the second wall 52 in a direction crossing the first wall 51 and the second wall 52. The first wall 51, the second wall 52, and the third wall 53 cover the third display portion 13 and conceal the third display portion 13 from the outside.

According to such a configuration, it is possible to improve the user-friendliness.

For comparison, an example of a bending-type table will be discussed. The tablet includes a liquid crystal displays that are independently provided to the first housing and the second housing, respectively. In this case, the two liquid crystal displays are separated, and visibility is damaged.

On the other hand, the electronic apparatus 21 according to the present embodiment includes the display 5 that extends from the first housing 6 to the second housing 7. Thus, images and videos are displayed on a continuous single display screen 5a. In this way, it is possible to improve visibility and to improve user-friendliness. In addition, it is possible to relieve a mounting limitation in relation to mounting of the large display 5 and to enlarge a screen size at the same footprint.

On the other hand, when the display 5 that extends from the first housing 6 to the second housing 7 is employed, if the display 5 is fixed to the first housing 6 and the second housing 7, the display may be stretched or pulled when the first housing 6 and the second housing 7 are rotated. Such stretching or pulling may apply load to the display to thereby shorten the lifespan of the electronic apparatus 21.

Therefore, in the present embodiment, the display 5 includes a portion which is configured to be slid within the first housing 6. In this way, when the second housing 7 is rotated relative to the first housing 6, the display 5 is moved relative to the first housing 6, and the display 5 can be suppressed from being stretched or pulled. As a result, large stress is not applied to the display 5 when the first housing 6 and the second housing 7 are rotated, and no problem occurs in the display 5. Therefore, it is possible to improve the lifespan of the electronic apparatus 21.

In the present embodiment, the display 5 includes the supporter 41 that is attached to the display 5, is configured to be guided to the first housing 6, and is slid within the first housing 6. By forming such a supporter 41, the display 5 is smoothly moved within the first housing 6. This further suppresses a large stress from acting on the display 5 and further improves the lifespan of the electronic apparatus 21.

In the present embodiment, the display 5 includes the first display portion 11 that is slid within the first housing 6 and the second display portion 12 that is fixed to the second housing 7. According to such a configuration, the display 5 can be stably supported by the second housing 7.

In the present embodiment, the first housing 6 includes the guiding portion 45 that extends in the sliding direction of the first display portion 11, to which the supporter 41 is guided. By forming such a guiding portion 45, the first display portion 11 can be further smoothly slid. This further suppresses a large stress from acting on the display 5 and further improves the lifespan of the electronic apparatus 21.

In the present embodiment, the second display portion 12 includes the fixing portion 37 that is provided by extending a part of the display 5. According to such a configuration, it is possible to decrease the number of components required for fixing the display. This contributes to reducing the cost of the electronic apparatus 21.

In the present embodiment, the first display portion 11 includes the end portion 11c that extends in the sliding direction of the first display portion 11. The supporter 41 extends substantially over the entire length of the end portion 11c. According to such a configuration, bending of the display 5 in the sliding direction of the first display portion 11 is further suppressed. In this way, it is possible to maintain high display quality of the display 5.

In the present embodiment, the display 5 includes the third display portion 13 that is positioned between the first display portion 11 and the second display portion 12. The third display portion 13 projects outward from a position between the first housing 6 and the second housing 7 in a state where the first housing 6 and the second housing 7 overlap each other, and is bent to form a circular arc that has a diameter greater than the gap between the first display portion 11 and the second display portion 12. According to such a configuration, the third display portion 13 is bent to form a circular arc having a relatively large curvature, and large load is hardly applied to the third display portion 13. This further suppresses a large stress from acting on the display 5 and further improves the lifespan of the electronic apparatus 21.

### Third Embodiment

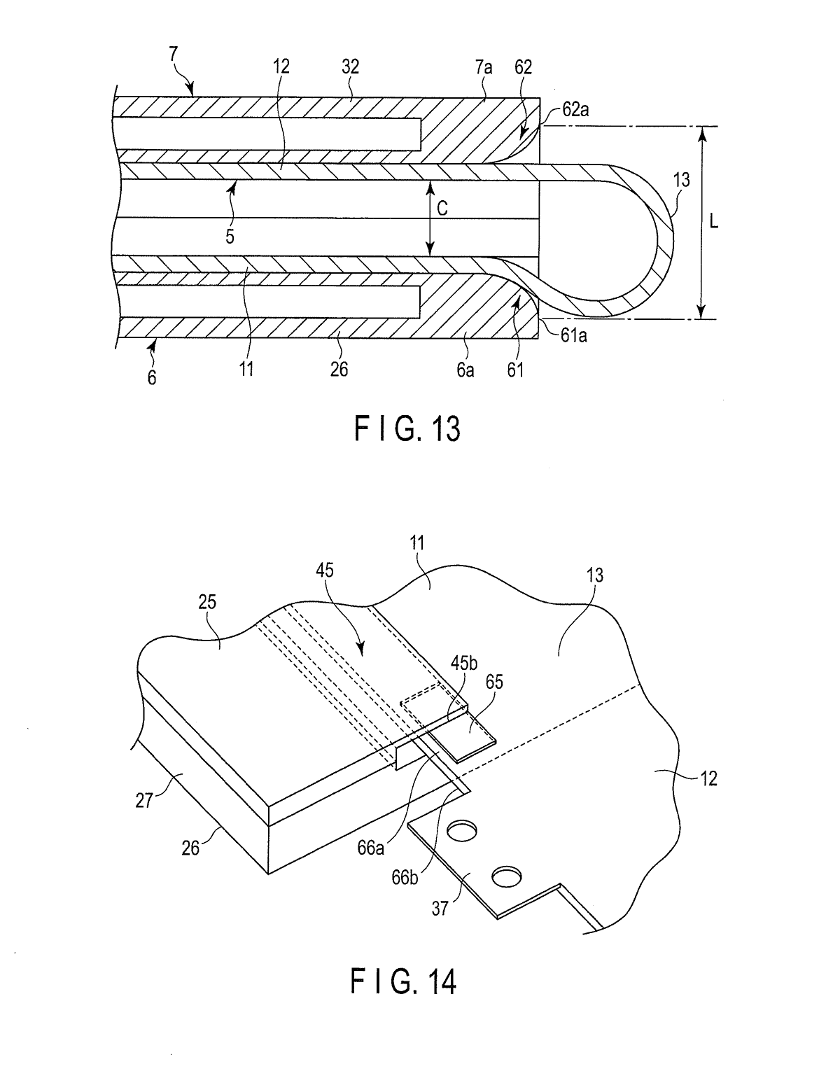

Next, an electronic apparatus 21 according to a third embodiment will be described with reference to FIGS. 12 and 13. Further, in the third embodiment, components having the same or similar functions as those in the first and second embodiments are denoted by the same reference numerals and a description thereof will not be repeated. In addition, structures other than the following structures are the same as those in the second embodiment.

As illustrated in FIGS. 12 and 13, in the present embodiment, the first end portion 6a of the first housing 6 includes a first slope 61 (i.e., inclined portion) so that the third display portion 13 is bent to form a circular arc that has a diameter greater than the gap C between the first display portion 11 and the second display portion 12. The first slope 61 is inclined away from the second housing 7 as the first slope 61 advances toward the rear side of the first housing 6. Further, the first slope 61 may be an inclined plane and may be a curved surface.

Similarly, the first end portion 27a of the second housing 7 includes a second slope 62 (i.e., inclined portion) so that the third display portion 13 is bent to form a circular arc that has a diameter greater than the gap C between the first display portion 11 and the second display portion 12. The second slope 62 is inclined away from the first housing 6 as the second slope 62 advances toward the rear side of the second housing 7. Further, the second slope 62 may be an inclined plane and may be a curved surface.

Here, as illustrated in FIG. 13, the distance L (i.e., dimension) between the end portion 61a of the first slope 61 and the end portion 62a of the second slope 62 is set to be equal to or more than twice the minimum radius of bending of the display 5. Further, the electronic apparatus 21 may include any one of the first slope 61 and the second slope 62.

According to such a configuration, similarly to the second embodiment, it is possible to improve the user-friendliness. Further, in the present embodiment, the end portion of the first housing 6 includes the slope 61 that is inclined away from the second housing 7. According to such a configuration, the radius of bending of the third display portion 13 increases and a large load is more hardly applied to the third display portion 13. This further suppresses a large stress from acting on the display 5 and further improves the lifespan of the electronic apparatus 21.

### Fourth Embodiment

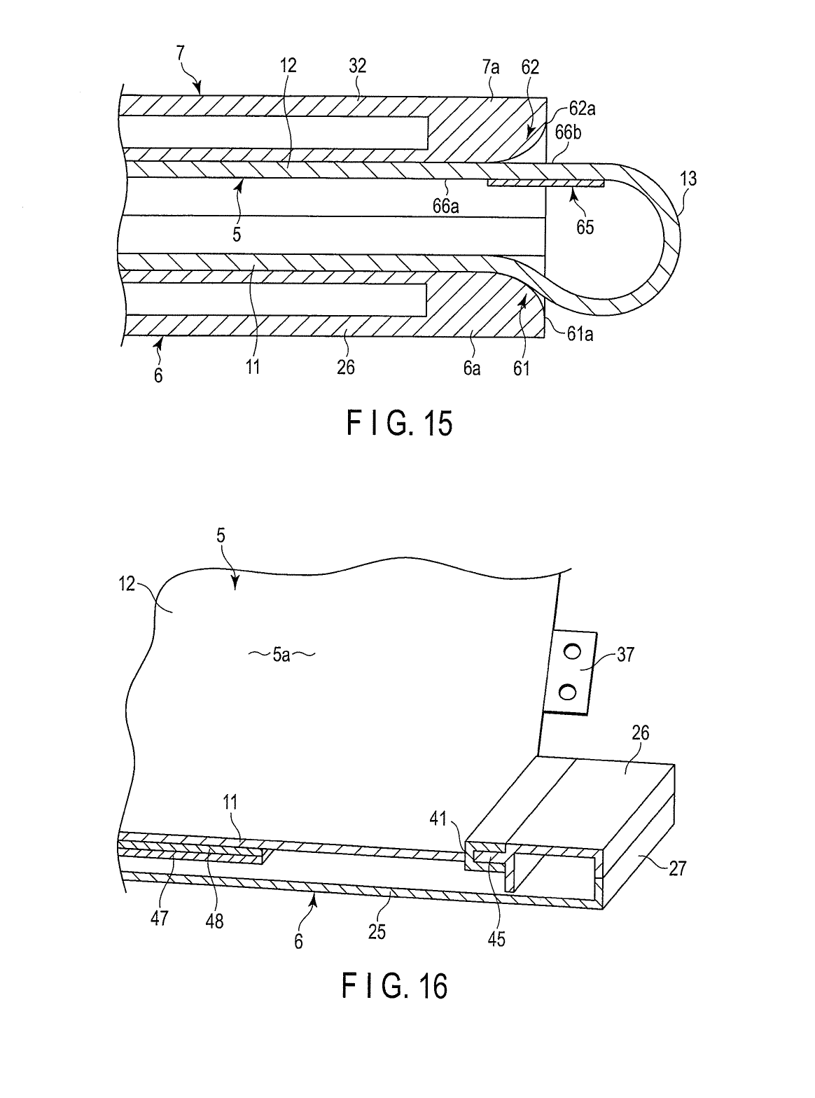

Next, an electronic apparatus 21 according to a fourth embodiment will be described with reference to FIGS. 14 and 15. Further, in the fourth embodiment, components having the same or similar functions as those in the first to third embodiments are denoted by the same reference numerals and a description thereof will not be repeated. In addition, structures other than the following structures are the same as those in the third embodiment.

As illustrated in FIG. 14, in the present embodiment, the third display portion 13 includes an elastic portion 65 (i.e., a reinforcing portion, a reinforcing plate, a pressing portion, or a guide). The display 5 includes a first surface 66a that includes the display screen 5a and a second surface 66b that is positioned on a side opposite to the first surface 66a. The elastic portion 65 is attached to the first surface 66a of the display 5.

The elastic portion 65 is a material that is harder than the display 5 and has elastic (i.e., spring) properties. The elastic portion 65 is pressed in the extending direction of the third display portion 13 when the first housing 6 and the second housing 7 overlap each other. That is, the elastic portion 65 presses the third display portion 13 toward the rear side. The elastic portion 65 assists in (i.e., accelerates) the sliding and folding operation of the display 5.

According to such a configuration, similarly to the second embodiment, it is possible to improve the user-friendliness. Further, in the present embodiment, the electronic apparatus 21 further includes the elastic portion 65 that presses the third display portion 13 in the extending direction of the third display portion 13 when the electronic apparatus 21 is closed. According to such a configuration, the first display portion 11 is more easily slid toward the rear side. This further suppresses a large stress from acting on the display 5 and further improves the lifespan of the electronic apparatus 21.

### Fifth Embodiment

Next, an electronic apparatus 21 according to a fifth embodiment will be described with reference to FIG. 16. In the fifth embodiment, components having the same or similar functions as those in the first to fourth embodiments are denoted by the same reference numerals and a description thereof will not be repeated. In addition, structures other than the following structures are the same as those in the second embodiment.

As illustrated in FIG. 16, the supporter 41 according to the present embodiment is a rail (i.e., a guide rail, a slide rail, or a groove). On the other hand, the guiding portion 45 of the first housing 6 is a projecting portion (i.e., a projection or a plate portion) that is guided to the rail. In the present embodiment, the supporter 41 which is a rail is slid by being guided to the guiding portion 45 which is a projecting portion.

According to such a configuration, similarly to the second embodiment, it is possible to improve the user-friendliness.

### Sixth Embodiment

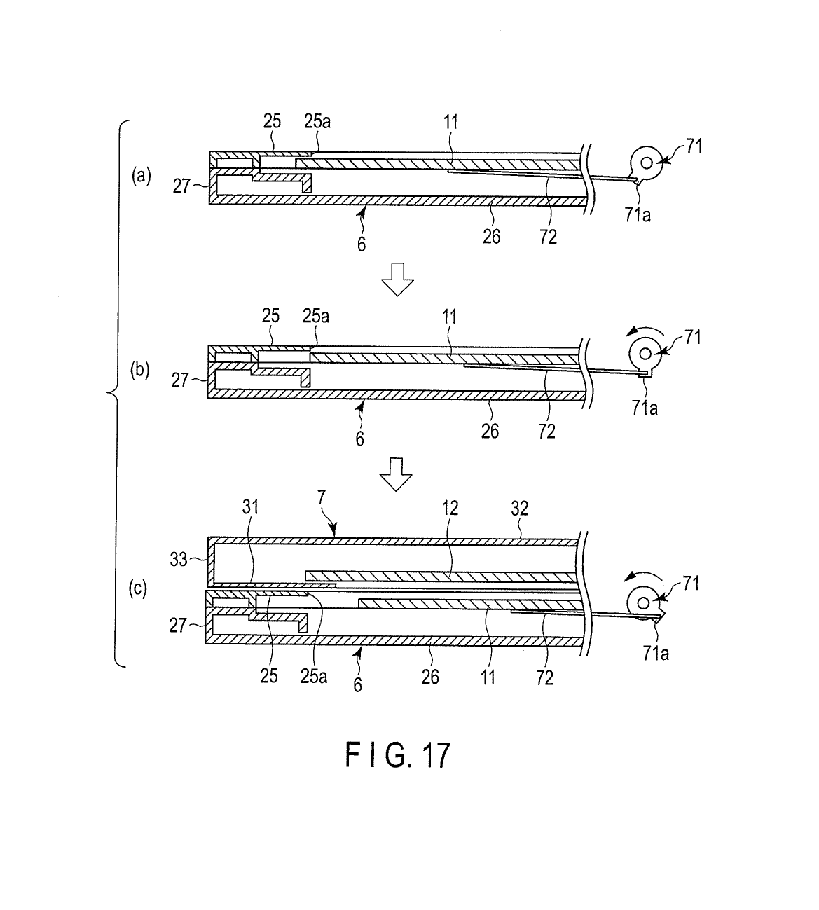

Next, an electronic apparatus 21 according to a sixth embodiment will be described with reference to FIG. 17. In the sixth embodiment, components having the same or similar functions as those in the first to fifth embodiments are denoted by the same reference numerals and a description thereof will not be repeated. In addition, structures other than the following structures are the same as those in the second embodiment.

In the present embodiment, the hinge 8a includes a rotating portion 71 that rotates when the first housing 6 and the second housing 7 are rotated. The rotating portion 71 includes a projection 71a that projects in the radial direction of the rotating portion 71. The projection 71a is connected to the first display portion 11 via a connecting member 72. An example of the connecting member 72 is a wire.

In the present embodiment, the rotating portion 71 of the hinge 8a rotates when the first housing 6 and the second housing 7 are rotated. When the rotating portion 71 rotates, the projection 71a moves, and the first display portion 11 is pulled or pushed by the connecting member 72. That is, the first display portion 11 is slid by being interlocked to the pivoting of the hinge 8a.

According to such a configuration, similarly to the second embodiment, it is possible to improve the user-friendliness. Further, in the present embodiment, the first display portion 11 is slid by being interlocked to the pivoting of the hinge 8a. According to such a configuration, it is possible to stably slide the first display portion 11. In this way, it is possible to further suppress a large stress from acting on the display 5 and to further improve the lifespan of the electronic apparatus 21.

### Seventh Embodiment

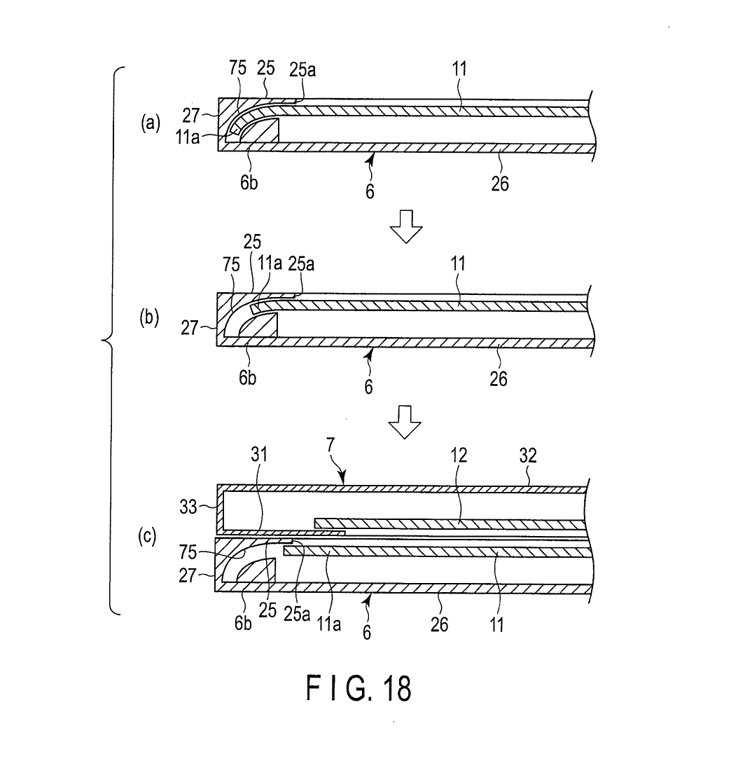

Next, an electronic apparatus 21 according to a seventh embodiment will be described with reference to FIG. 18. In the seventh embodiment, components having the same or similar functions as those in the first to sixth embodiments are denoted by the same reference numerals and a description thereof will not be repeated. In addition, structures other than the following structures are the same as those in the second embodiment.

As illustrated in FIG. 18, in the present embodiment, a guiding portion 75 is provided in the second end portion 6b of the first housing 6. The guiding portion 75 guides the first end portion 11a of the first display portion 11 so that the first end portion 11a is bent in the thickness direction of the first housing 6. In this way, the first end portion 11a of the first display portion 11 is bent toward the inner side of the second end portion 6b of the first housing 6 and is received in the first housing 6.

According to such a configuration, similarly to the second embodiment, it is possible to improve the user-friendliness. Further, in the present embodiment, the guiding portion 75 of the first housing 6 allows the first end portion 11a of the first display portion 11 to be bent in the thickness direction of the first housing 6 and be received in the first housing 6. In this way, it is possible to increase the size of the first opening 31a of the first housing 6 through which the first display portion 11 is exposed. In other words, it is possible to provide the electronic apparatus 21 having a narrow frame.

### Eighth Embodiment

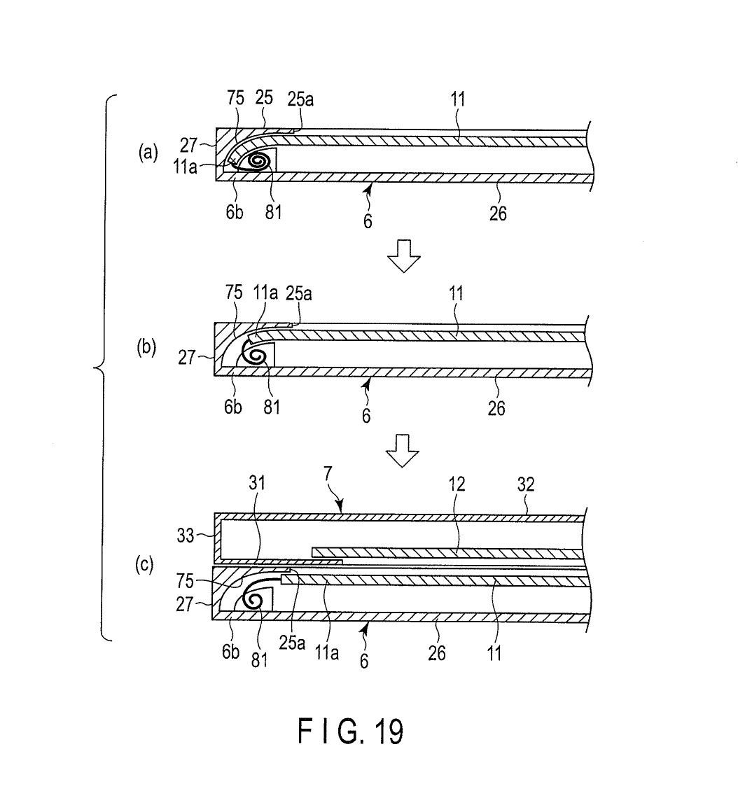

Next, an electronic apparatus 21 according to an eighth embodiment will be described with reference to FIG. 19. In the eighth embodiment, components having the same or similar functions as those in the first to seventh embodiments are denoted by the same reference numerals and a description thereof will not be repeated. In addition, structures other than the following structures are the same as those in the seventh embodiment.

As illustrated in FIG. 19, an elastic portion 81 is provided in the first housing 6. The elastic portion 81 pulls the first display portion 11 toward a side opposite to the second display portion 12 (i.e., a side opposite to the second end portion 11b) so that the first display portion 11 is not bent in the sliding direction of the first display portion 11. That is, the elastic portion 81 applies tension to the first display portion 11.

According to such a configuration, similarly to the second embodiment, it is possible to improve the user-friendliness. Further, in the present embodiment, the first housing 6 includes the elastic portion 81 that pulls the first display portion 11 toward a side opposite to the second display portion 12. According to such a configuration, the first display portion 11 is hardly flexible. In this way, it is possible to maintain high display quality of the display 5.

### Ninth Embodiment

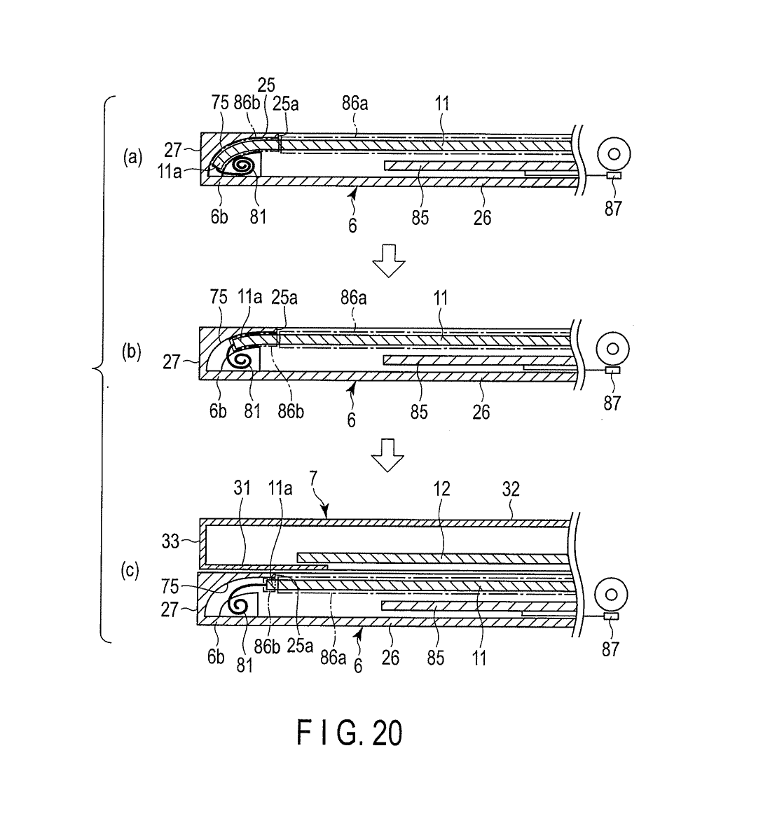

Next, an electronic apparatus 21 according to a ninth embodiment will be described with reference to FIG. 20. In the ninth embodiment, components having the same or similar functions as those in the first to eighth embodiments are denoted by the same reference numerals and a description thereof will not be repeated. In addition, structures other than the following structures are the same as those in the eighth embodiment.

As illustrated in FIG. 20, in the present embodiment, the first housing 6 accommodates a circuit board 85. The circuit board 85 controls an active area 86a and a non-active area 86b of the display 5. The active area 86a is an area on which images or videos are displayed. The non-active area 86b is an area on which images or videos are not displayed. The circuit board 85 may be accommodated in the second housing 7 or the third housing 23.

As illustrated in FIG. 20, the electronic apparatus 21 includes a sensor 87 that detects a rotation angle of the hinge 8a. The sensor 87 is electrically connected to the circuit board 85. The circuit board 85 receives a signal from the sensor 87 and detects a positional relation between the first display portion 11 and the first opening 31a based on the rotation angle of the hinge 8a.

The circuit board 85 controls a portion of the first display portion 11 exposed from the first opening 31a as the active area 86a and also controls a portion that is not exposed from the first opening 31a as the non-active area 86b. That is, the active area 86a of the first display portion 11 sequentially increases or decreases based on the rotation angle of the hinge 8a.

According to such a configuration, similarly to the second embodiment, it is possible to improve the user-friendliness. Further, in the present embodiment, the active area 86a of the first display portion 11 changes based on the rotation angle of the hinge 8a. According to such a configuration, it is possible to use an appropriate region of the first display portion 11 as the active area 86a and to improve the user-friendliness.

### Tenth Embodiment

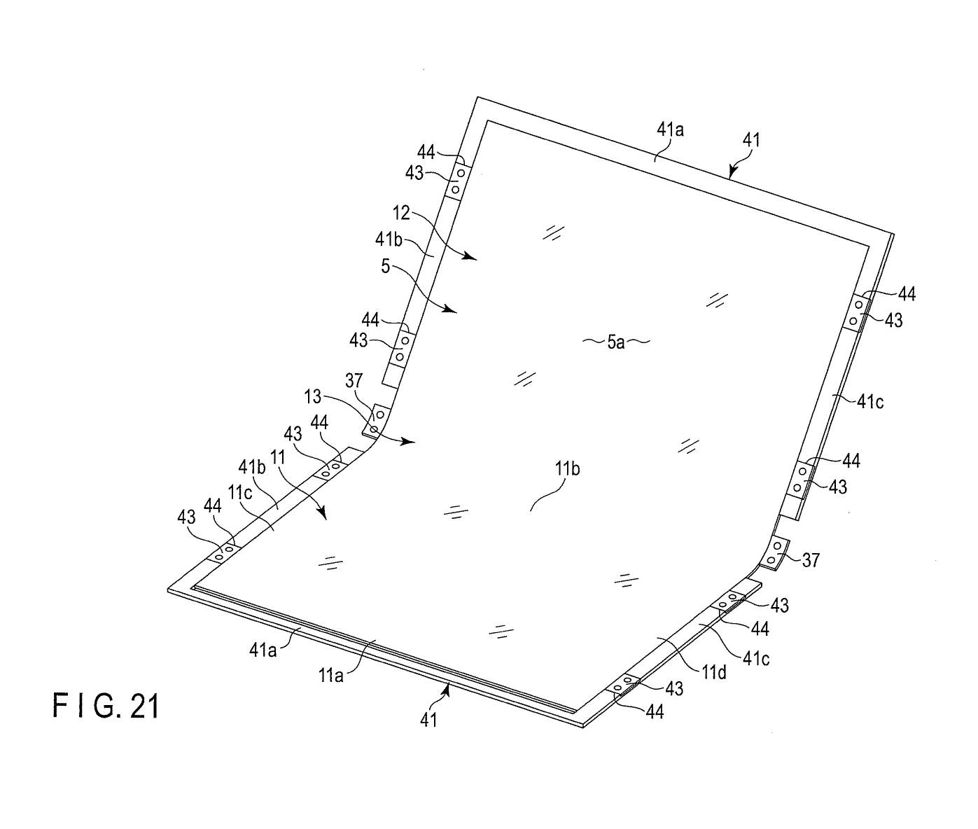

Next, an electronic apparatus 21 according to a tenth embodiment will be described with reference to FIG. 21. In the tenth embodiment, components having the same or similar functions as those in the first to eighth embodiments are denoted by the same reference numerals and a description thereof will not be repeated. In addition, structures other than the following structures are the same as those in the second embodiment.

As illustrated in FIG. 21, in the present embodiment, the third display portion 13 includes a fixing portion 37. The fixing portion 37 is fixed to the hinges 8a and 8b. That is, in the present embodiment, the display 5 is fixed to the hinges 8a and 8b. On the other hand, the second display portion 12 includes the supporter 41 similarly to the first display portion 11. The second display portion 12 is slid within the second housing 7 when the first housing 6 and the second housing 7 are rotated. The supporter 41 provided in the second display portion 12 is configured to be guided to the second housing 7 and slid within the second housing 7 when the first housing 6 and the second housing 7 are rotated. The second housing 7 includes a guiding portion 45 that guides the supporter 41 similarly to the first housing 6.

According to such a configuration, similarly to the second embodiment, it is possible to improve the user-friendliness.

The embodiments are not limited to the embodiments described above but may be realized by modifying constituent elements in the implementing step within a range without departing from the spirit of the invention. Moreover, various embodiments can be made by appropriately combining a plurality of constituent elements disclosed in the embodiments described above. For example, some constituent elements may be omitted from all constituent elements disclosed in the embodiments. Furthermore, constituent elements in different embodiments may be combined appropriately.

For example, the hinges are not essential constituent components. Some of the above embodiments can be applied to a bending-type electronic apparatus which does not have a hinge.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. A television comprising:
a first exterior member;
a second exterior member;
a hinge configured to rotatably connect the first exterior member and the second exterior member;
a flexible display extending from the first exterior member to the second exterior member, the flexible display comprising
a first portion configure to slide in the first exterior member when the second exterior member is rotated relative to the first exterior member, and
a second portion fixed to the second exterior member; and
a supporter attached to the first portion of the flexible display, the supporter configured to be guided by the first exterior member when the second exterior member is rotated relative to the first exterior member, and to slide in the first exterior member.

2. The television of claim 1, wherein
the first exterior member comprises a guide extending in a sliding direction of the first portion of the flexible display, the guide configured to guide the supporter.

3. The television of claim 1, wherein
the second portion comprises a fixing portion extending from the flexible display.

4. The television of claim 1, wherein
the first portion comprises an end extending in a sliding direction of the first portion of the flexible display, and
the supporter extends substantially along an entire length of the end of the first portion of flexible display so that the first portion avoids bending in the sliding direction.

5. The television of claim 1, wherein
the flexible display includes a third portion between the first portion and the second portion, and
the third portion is configured to project outward from a position between the first exterior member and the second exterior member in a state where the first exterior member and the second exterior member overlap each other, the third portion configured to be bent to form a circular arc which has a diameter greater than a gap between the first portion and the second portion.

6. The television of claim 5, wherein
an end portion of the first exterior member comprises a slope inclined away from the second exterior member so that the third portion of the flexible display is bent to form the circular arc.

7. The television of claim 5, further comprising
an elastic portion harder than the flexible display, the elastic portion attached to the third portion of the flexible display and configured to press the third portion in an extending direction of the third portion when the first exterior member and the second exterior member overlap each other.

8. The television of claim 1, further comprising
an elastic portion in the first exterior member, the elastic portion configured to pull the first portion of the flexible display toward a side opposite to the second portion of the flexible display so that the first portion is not bent in the sliding direction.

9. An electronic apparatus comprising:
a first housing;
a second housing configured to be rotated relative to the first housing;
a flexible display comprising a portion configured to slide in the first housing when the second housing is rotated relative to the first housing, the flexible display extending from the first housing to the second housing; and
a supporter attached to the portion of the flexible display, the supporter configured to be guided by the first housing and to slide in the first housing.

10. An electronic apparatus comprising:
a housing;
a display configured to be movable relative to the housing; and
a supporter attached to the display and configured to be movable in the housing.
